(19) United States
(12) Patent Application Publication
(10) Pub. No.: US 2007/0246814 A1
(43) Pub. Date: Oct. 25, 2007

(54) Ball Grid array package structure

(75) Inventors: Wen-Jeng Fan, Hsinchu (TW); Li-chih Fang, Hsinchu (TW); Ronald Iwata, Ooita City (JP)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/508,882

(22) Filed: Aug. 24, 2006

(30) Foreign Application Priority Data
Apr. 21, 2006 (TW) 95206884

(51) Int. Cl. H01L 23/02

(52) U.S. Cl. 257/686

(57) ABSTRACT

A ball grid array structure includes a substrate, wherein a plurality of electric contacts are arranged on its lower surface; a chip arranged on the upper surface of the substrate and electrically connecting with those electric-connecting points; at least a through hole on the substrate and arranged around the edge of the chip; a molding compound covering the chip and filling the through hole to form a window-type bump on the lower surface of the substrate; and a plurality of conductive balls arranged on those electric-connecting points on the substrate. The present invention utilizes the window-type bump to enhance the structure strength of the substrate to effectively decrease the warpage of package in the curing process and to provide a support to prevent the crack of the package from the external force.

### BACKGROUND OF THE INVENTION

1. Field of the Invention

The present invention relates to a semiconductor package structure, particularly to a BGA (Ball Grid Array) package structure.

2. Description of the Related Art

A semiconductor package structure is used to carry an active electronic element, such as a semiconductor chip. Refer to FIG. 1 a sectional view schematically showing a conventional BGA (Ball Grid Array) package structure that mounted on a PCB. As shown in FIG. 1, in the conventional BGA package structure, a chip 110 is arranged on the surface of a substrate 100, and the chip 110 is electrically connected with the substrate 100 via a wire bonding process; a encapsulant 130 is used to cover the chip 110 and conductive wires 120; a plurality of solder balls 140 are arranged in an array on the other side of the substrate 100 and function as I/O (Input/Output) terminals so that the chip 110 carried by the package structure can be electrically connected with an external device, such as a PCB (Printed Circuit Board) 150. With the development of the semiconductor industry, CSP (Chip Scale Package) has been extensively adopted to meet the trend of high capacity and multiple-function integration in electronic products, particularly in high-capacity memory chips. As shown in FIG. 1, when the conventional package structure is arranged to an external device via an SMT (Surface Mount Technology) process, external force F is apt to damage the internal chip or crack the corner/the perimeter of the package structure.

In addition to the trend of high capacity, thin package is also a trend of semiconductor package. Refer to FIG. 2, a sectional view schematically showing a conventional wBGA (window Ball Grid Array) package structure that mounted on a PCB. As shown in FIG. 2, a wBGA package structure is still more fragile, and external force F is still more likely to crack the structure or damage the chip. A conventional solution is to add an underfill resin into the gap between the package structure and the PCB; thus, the support force is enhanced; however, such a method will add extra cost of the underfill resin and the related process into the fabrication cost. Another conventional solution is to add extra dummy balls to the surface of the package structure; however, such a method not only adds extra cost of the dummy balls into the fabrication cost but also needs an extra ball-installation region of the PCB.

When the temperature of the package structure rises, the difference in the thermal expansion coefficients of the package materials usually causes the warpage of the package structure. With the development of thin package technology, the warpage problem grows still more serious. Therefore, the solution of the above-mentioned problems is eagerly desired by the industry.

### SUMMARY OF THE INVENTION

The present invention proposes a BGA (Ball Grid Array) package structure with window-type bump to overcome the above-mentioned problems.

The primary objective of the present invention is to provide a BGA package structure, which can avoid the warpage occurring in the curing process after the encapsulant has been filled into the mold.

Another objective of the present invention is to provide a BGA package structure, wherein after the SMT (Surface Mount Technology) process, the window-type bump below the substrate can provide a structural support for the package structure lest the package structure be damaged by external force.

To achieve the above-mentioned objectives, the BGA package structure disclosed in one embodiment of the present invention includes: a substrate, wherein a plurality of electric contacts are arranged on a lower surface of the substrate; a chip arranged on a upper surface of the substrate and electrically connected with those electric contacts; at least one through hole penetrating the substrate and disposed in the perimeter around the chip; an encapsulant covering the chip and filling those through holes to form a window-type bump on the lower surface of the substrate; and a plurality of conductive balls arranged to those electric contacts of the substrate. To enable the objectives, technical contents, characteristics and accomplishments of the present invention to be more easily understood, the embodiments of the present invention are to be described in detail in cooperation with the attached drawings below.

### BRIEF DESCRIPTION OF THE DRAWINGS

FIG. 1 is a sectional view schematically showing a conventional BGA package structure that mounted on a PCB;

FIG. 2 is a sectional view schematically showing a conventional wBGA package structure that mounted on a PCB;

FIG. 3A is a sectional view schematically showing the BGA package structure according to one embodiment of the present invention;

FIG. 3B is a bottom view schematically showing the embodiment illustrated in FIG. 3A;

FIG. 4A and FIG. 4B are sectional views schematically the fabrication process of the BGA package structure according to one embodiment of the present invention; and

FIG. 4C and FIG. 4D are sectional views schematically showing the electronic packaging structures of the BGA package structures respectively according to different embodiments of the present invention.

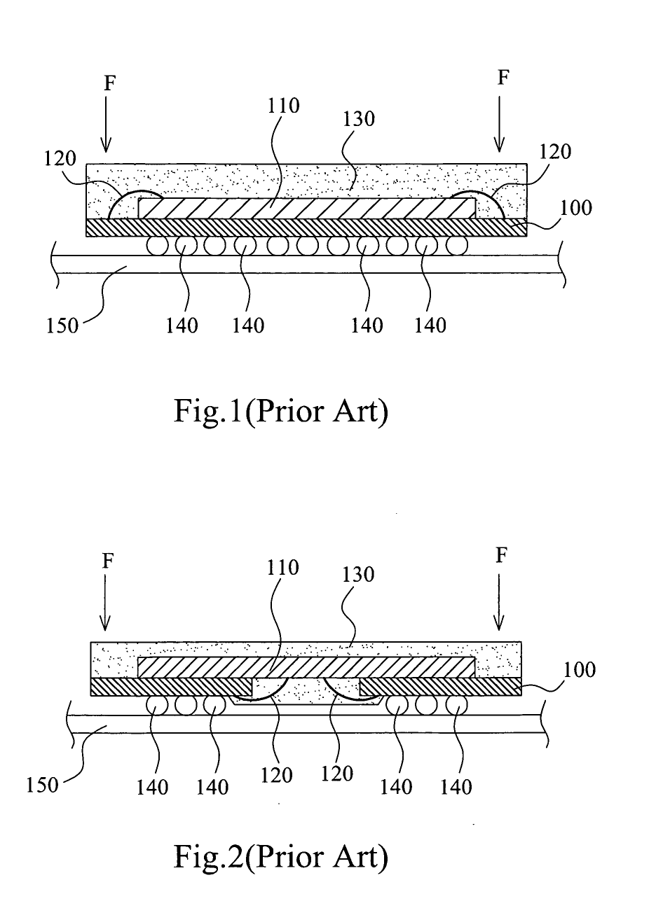

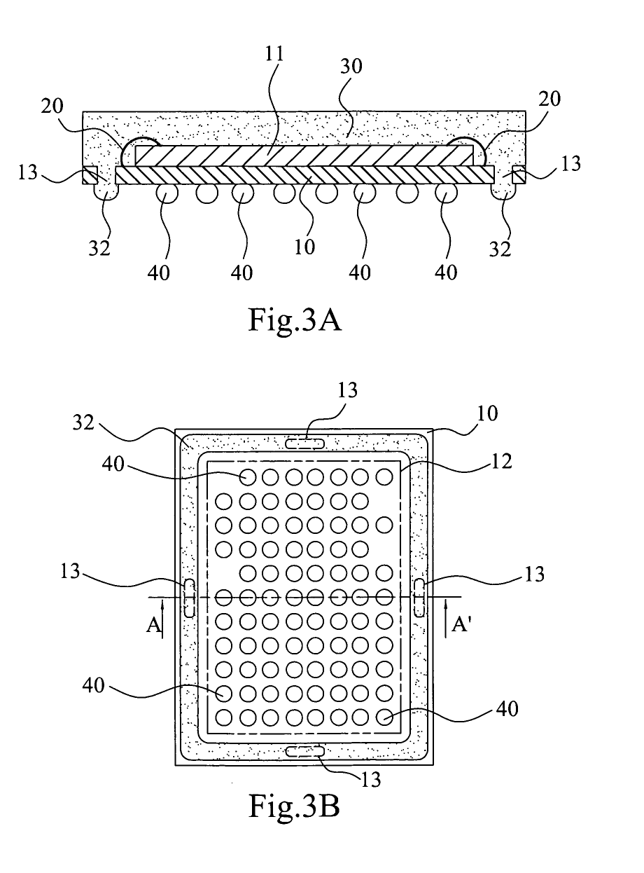

### DETAILED DESCRIPTION OF THE INVENTION

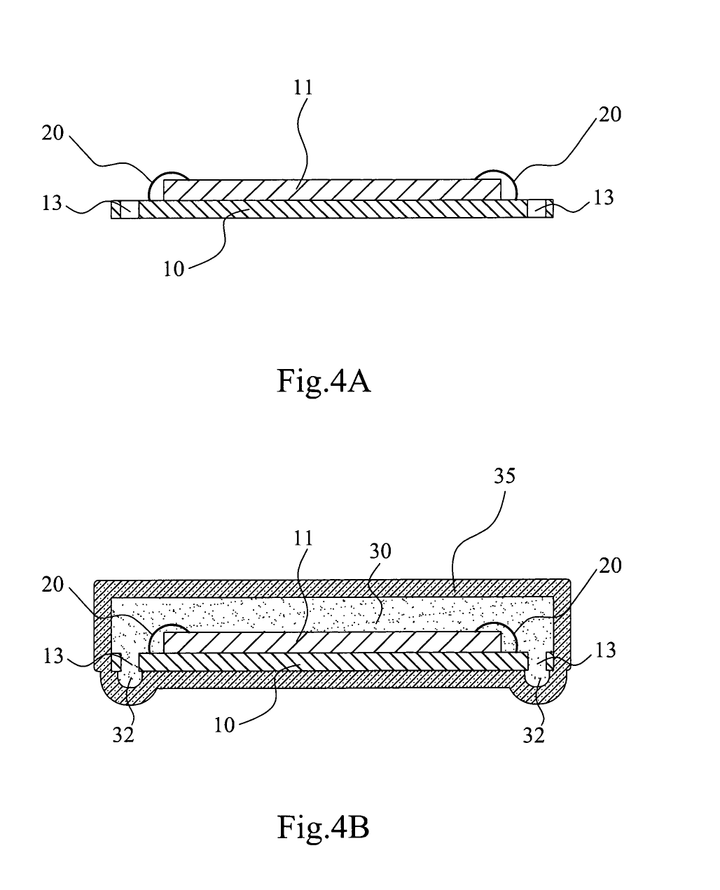

Refer to FIG. 3A a sectional view schematically showing the BGA package structure according to one embodiment of the present invention. As shown in FIG. 3A, the BGA package structure includes: a substrate 10; a chip 11 arranged on a upper surface of the substrate 10; a plurality of through holes penetrating the substrate 10 and disposed around the perimeter of the chip 11; an encapsulant 30 covering the chip 11 and filling those through holes 13 to form a window-type bump 32 on a lower surface of the substrate 10; and a plurality of conductive balls 40 arranged on the lower surface of the substrate 10, wherein a plurality of electric contacts (not shown in the drawing) are formed on the lower surface of the substrate 10, and the chip 11 is electrically connected with those electric contacts, and those conductive balls 40 are disposed on those electric contacts. In this embodiment, the material of the substrate 10 is selected from the group consisting of polyimide, glass fiber, alumina, epoxy, beryllium oxide and elastomer. The chip 11 is electrically connected to those electric contacts with a plurality of metallic lead wires 20, such as conductive wires, via a wiring bonding process. The encapsulant 30 is essentially composed of epoxy resin and filler, and those conductive balls 40 are conductive solder balls.

Refer to FIG. 3B, a bottom view schematically showing the embodiment illustrated in FIG. 3A, wherein FIG. 3A is the sectional view along line A-A′ in FIG. 3B. As shown in FIG. 3B, those conductive balls 40 are disposed within the electric-contact region 12 on the lower surface of the substrate 1 1, and the window-type bump 32 simultaneously formed with the encapsulant 30 and to encircle those conductive balls 40. After the encapsulant material has been compressively filled into the mold, a curing process is undertaken, and the window-type bump 32 can enhance the strength of the substrate 10 in the curing process; thus, the window-type bump 32 can balance the mismatch of thermal expansion coefficients, reduce the thermal warpage resulting from the difference in thermal expansion coefficients of the encapsulant 30, the substrate 10, the chip and other materials. The application of the encircling bumps 32 is not limited to the BGA package structure shown in this embodiment. The encircling bump 32 may also apply to the FBGA (Fine pitch Ball Grid Array) package structure, the VFBGA (Very Fine pitch Ball Grid Array) package structure, the BGA (micro Ball Grid Array) package structure and the wBGA (window Ball Grid Array) package structure. As shown in FIG. 3B, there are a plurality of through holes 13; however, the present invention is not limit to the case shown in FIG. 3B. In cooperation with different mold designs, the encircling bump may be fabricated via a plurality of through holes or even only one through holes. The shape of the through hole 13 may be a circle, an ellipse, a polygon, a strip, or a multiple-arc shape.

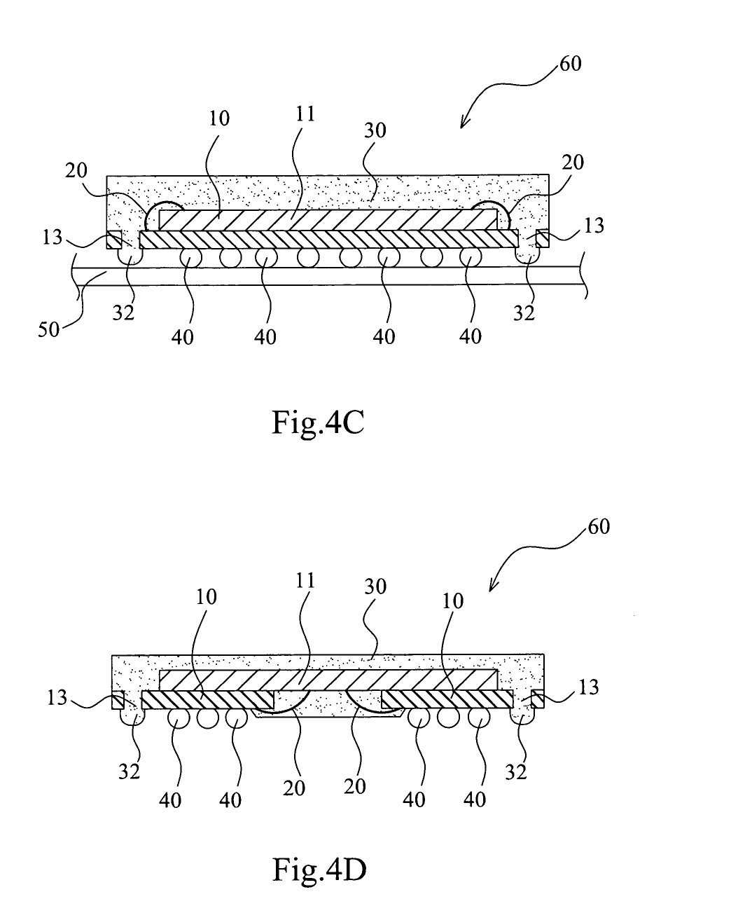

Refer to FIG. 4A and FIG. 4B sectional views schematically the fabrication process of the BGA package structure according to one embodiment of the present invention, wherein FIG. 4A is a sectional view schematically showing that a chip is stuck onto a substrate, and FIG. 4B is a sectional view schematically showing that the chip and the substrate is packaged via compressively filling a packaging resin into a mold. As shown in FIG. 4A, a chip 11 is arranged on a substrate 10 firstly; next, the chip 11 and the substrate 10 are electrically interconnected with a plurality of metallic lead wires 20. Next, as shown in FIG. 4B, the chip 11 together with the substrate 10 is placed inside a mold 35; next, a encapsulant 30 is compressively filled into the mold 35 so that the encapsulant 30 can cover the chip 11, the substrate 10 and those metallic lead wires 20 and pass through those through holes 13 to completely fill the mold 35 with electric contacts (not shown in the drawing) exposed on the lower surface of the substrate 10. Next, a curing process is used to fully harden the encapsulant 30. The encapsulant 30 passing through those through holes 13 is also hardened to form the encircling bump 32. Next, as shown in FIG. 3A, a plurality of conductive balls 40 are arranged on the lower surface of the substrate 10 and respectively electrically connected to those electric contacts, and the BGA package structure is thus completed.

Refer to FIG. 4C and FIG. 4D sectional views schematically showing the electronic packaging structures of the BGA package structures respectively according to different embodiments of the present invention. As shown in FIG. 4C, the electronic packaging structure of the BGA package structure includes: a printed circuit board 50 and a BGA package structure 60. The BGA package structure 60 has a plurality of conductive balls 40 arranged on the lower surface thereof and has window-type bump 32 arranged in the perimeter of the lower surface and encircling those conductive balls 40. The printed circuit board 50 has an electric-connection region (not shown in the drawing); the BGA package structure 60 is fixed to and electrically connected to the electric-connection region of the printed circuit board 50 via those conductive balls 40. The height of the encircling bump 32 of the BGA package structure 60 is not greater than the spacing between the BGA package structure 60 and the printed circuit board 50 so that the bump will exactly touch the printed circuit board 50 or will not touch the printed circuit board 50 until external force acts on the BGA package structure 60. Thereby, the bump 32 can provide a support for the BGA package structure 60 lest the BGA package structure 60 be damaged by external force. The printed circuit board 50 further includes a plurality of conductive solder pads (not shown in the drawing), which corresponds to those conductive balls 40 and are fixed to those conductive balls 40 to form the electric connection therebetween. The description of the structure of the BGA package structure 60 has been stated above and will not repeat here. The BGA package structure 60 may also be a FBGA package structure, a VFBGA package structure, a. BGA package structure, or a wBGA package structure.

Refer to FIG. 4D a sectional view schematically showing the present invention applies to the electronic packaging structure of a wBGA package structure. Such a thin package structure is very fragile, and the chip 11 thereof is apt to be damaged by external force. In this embodiment, the encircling bump 32 may provide a support for the package structure lest the package structure be cracked by external force. When the user assembles the semiconductor module, the present invention can prevent the package structure from being damaged by external force, such as too great a force applied by the user. Thereby, the yield and lifetime of the package structure can be increased, and the economic efficiency can also be promoted.

In summary, the present invention utilizes the window-type bump to improve the package structure. Thereby, in the curing process succeeding to the resin-filling process, the warpage of the package structure can be effectively reduced. Further, after the package structure has been assembled with an SMT process, the window-type bump can also provide a support for the package structure lest the package structure be damaged by external force. Furthermore, the encircling bumps of the package structure are simultaneously formed with the encapsulant body via compressively filling the encapsulant into the mold; thus, the encircling bumps are formed in the existing packaging process, and neither extra process nor extra cost is needed. Therefore, the present invention can raise yield and reduce cost simultaneously.

Although the present invention has been explained in relation to its preferred embodiment, it is to be understood that other modifications and variation can be made without departing the spirit and scope of the invention as hereafter claimed.

What is claimed is:

1. A ball grid array package structure, comprising:
a substrate, wherein a plurality of electric contacts are arranged on a lower surface of said substrate;
a chip arranged on a upper surface of said substrate and electrically connected to said electric contacts;
at least one through hole penetrating said substrate and disposed around the perimeter of said chip;
an encapsulant covering said chip and filling said through hole to form a window-type bump on said lower surface of said substrate; and
a plurality of conductive balls arranged on said electric contacts of said substrate.

2. The ball grid array package structure according to claim 1, wherein the material of said substrate is selected from the group consisting of polyimide, glass fiber, alumina, epoxy, beryllium oxide and elastomer.

3. The ball grid array package structure according to claim 1, wherein said chip is electrically connected to said electric contacts with a plurality of metallic lead wires.

4. The ball grid array package structure according to claim 1, wherein the material of said encapsulant is essentially composed of epoxy resin and filler.

5. The ball grid array package structure according to claim 1, wherein the material of said conductive balls is mainly composed of tin.

6. The ball grid array package structure according to claim 1, wherein the shape of said through hole may be a circle, an ellipse, a polygon, a strip, or a multiple-arc shape.

7. The ball grid array package structure according to claim 1, wherein said ball grid array package structure may be a FBGA (Fine pitch Ball Grid Array) package structure, a VFBGA (Very Fine pitch Ball Grid Array) package structure, a BGA (micro Ball Grid Array) package structure or a wBGA (window Ball Grid Array) package structure.

8. An electronic packaging structure, comprising:
a printed circuit board having an electric-connection region thereon; and
a ball grid array package structure having a plurality of conductive balls on the lower surface, wherein a window-type bump is disposed around the perimeter of said conductive balls and said ball grid array package structure is fixed to and electrically connected to said electric-connecting region of said printed circuit board via said conductive balls.

9. The electronic packaging structure according to claim 8, wherein said ball grid array package structure further comprises:
a substrate having a plurality of electric contacts on a lower surface;
a chip arranged on a upper surface of said substrate and electrically connected to said electric contacts;
at least one through hole penetrating said substrate and disposed around the perimeter of said chip; and
an encapsulant covering said chip and filling said through hole to form said window-type bump on said lower surface of said substrate.

10. The electronic packaging structure according to claim 9, wherein the material of said substrate is selected from the group consisting of polyimide, glass fiber, alumina, epoxy, beryllium oxide and elastomer.

11. The electronic packaging structure according to claim 9, wherein said chip is electrically connected to said electric contacts with a plurality of metallic lead wires.

12. The electronic packaging structure according to claim 9, wherein the material of said encapsulant is essentially composed of epoxy resin and filler.

13. The electronic packaging structure according to claim 9, wherein the material of said conductive balls is mainly composed of tin.

14. The electronic packaging structure according to claim 9, wherein the shape of said through hole may be a circle, an ellipse, a polygon, a strip, or a multiple-arc shape.

15. The electronic packaging structure according to claim 8, wherein said ball grid array package structure may be a FBGA (Fine pitch Ball Grid Array) package structure, a VFBGA (Very Fine pitch Ball Grid Array) package structure, a BGA (micro Ball Grid Array) package structure or a wBGA (window Ball Grid Array) package structure.

16. The electronic packaging structure according to claim 8, wherein said printed circuit board further comprises a plurality of conductive solder pads disposed on said electric-connection region to fix to and electrically connected to said conductive balls.
